(19) United States
(12) Patent Application Publication
(10) Pub. No.: US 2026/0324485 A1
(43) Pub. Date: Oct. 15, 2026

(54) PACKAGE STRUCTURE AND METHOD FOR FORMING THE SAME

(71) Applicant: JCET Management Co., LTD., Shanghai (CN)

(72) Inventor: Cheng YANG, Shanghai (CN)

(73) Assignee: JCET Management Co., LTD., Shanghai (CN)

(21) Appl. No.: 19/640,022

(22) Filed: Apr. 6, 2026

(30) Foreign Application Priority Data
Apr. 11, 2025 (CN) 202510455428.3

(51) Int. Cl. H10W 72/20; H10W 72/00; H10W 90/26

(52) U.S. Cl. CPC H10W 72/247; H10W 72/012; H10W 90/26

(57) ABSTRACT

A package structure and a method for forming the same are provided. The method includes: providing a chip stacked structure of first semiconductor chips, where a first side surface exposes side solder pads having non-coplanar defects. A second side surface is mounted to a carrier board so the first side surface faces away from the carrier board. A cladding layer is formed over the chip stacked structure. A planarization process removes a portion of the cladding layer, the first side surface, and the side solder pads. Solder bumps are then formed in electrical connection to the side solder pads. After removing the carrier board, the chip stacked structure is mounted to a substrate via the solder bumps, which are soldered to corresponding first solder pads on a surface of the substrate.

### CROSS-REFERENCE TO RELATED APPLICATIONS

This application claims the benefit of priority to Chinese Application No. 202510455428.3, filed on Apr. 11, 2025, which is incorporated herein by reference in its entirety.

### TECHNICAL FIELD

The present disclosure relates to the field of package technology, and particularly relates to a package structure and a method for forming the same.

### BACKGROUND

As chip miniaturization becomes increasingly difficult and the market's pursuit of high-performance chips remains undiminished, the industry has begun to explore breakthroughs in the field of package; in recent years, advanced IC package technologies such as 2.5D/3D have become a focal of attention for foundries, package and test factories, IDMs, chip design manufacturers and EDA manufacturers.

### SUMMARY

A package structure and a method for forming the same are provided.

In one aspect, the embodiments of the present disclosure provide a method for forming a package structure, which includes: providing a chip stacked structure, the chip stacked structure includes a plurality of first semiconductor chips stacked in sequence, and the chip stacked structure includes four side surfaces, and a side surface of the chip stacked structure exposes side solder pads of the corresponding side surfaces of the plurality of first semiconductor chips, and the side solder pads have non-coplanar defects; providing a carrier board, mounting a side surface of the chip stacked structure on the upper surface of the carrier board, such that the side surface of the chip stacked structure exposing the side solder pads is far away from the upper surface of the carrier board; forming a cladding layer covering the chip stacked structure; using a planarization process to remove a part of the cladding layer, a part of the side surface of the chip stacked structure far away from the upper surface of the carrier board, and a part of the side solder pads, such that the side solder pads of the different first semiconductor chips exposed on the side surface of the chip stacked structure far away from the upper surface of the carrier board are coplanar; after the planarization process, forming solder bumps electrically connected with the side solder pads; removing the carrier board; providing a substrate, the upper surface of the substrate has a plurality of discrete first solder pads; and mounting the side surface of the chip stacked structure exposing the side solder pads on the upper surface of the substrate, such that the solder bumps are soldered together with the corresponding first solder pads.

In some embodiments, the side solder pads are manufactured and formed synchronously with wiring layers of the first semiconductor chips.

In some embodiments, each of the first semiconductor chips in the chip stacked structure includes opposed active surface and back surface, as well as four side surfaces located between the active surface and the back surface, and one of the side surfaces of the first semiconductor chips has side solder pads and exposes the surfaces of the side solder pads, the active surfaces and back surfaces of the first semiconductor chips of the upper and lower layers in the chip stacked structure are arranged opposed to each other.

In some embodiments, in the chip stacked structure, the active surfaces of the first semiconductor chips of the upper layer and the back surfaces of the first semiconductor chips of the adjacent lower layer are arranged opposed to each other.

In some embodiments, in the chip stacked structure, the back surfaces of the first semiconductor chips of the upper layer and the active surfaces of the first semiconductor chips of the adjacent lower layer are arranged opposed to each other.

In some embodiments, there are no electrical connections between the first semiconductor chips of the upper layer and the semiconductor chips of the adjacent lower layer.

In some embodiments, an adhesive layer or a bonding layer is provided between the active surfaces or back surfaces of the first semiconductor chips of the upper layer and the corresponding back surfaces or active surfaces of the semiconductor chips of the adjacent lower layer.

In some embodiments, there are electrical connections between the first semiconductor chips of the upper layer and the semiconductor chips of the adjacent lower layer.

In some embodiments, the active surfaces of the first semiconductor chips have external solder pads, the first semiconductor chips have in them through-hole connection structures electrically connected with the external solder pads, and the back surfaces of the first semiconductor chips expose an end surface of the through-hole connection structures, and the external solder pads on the active surfaces or the through-hole connection structures on the back surfaces of the first semiconductor chips in the upper layer are soldered together with the through-hole connection structures on the corresponding back surfaces or the external solder pads on the active surfaces of the semiconductor chips of the adjacent lower layer.

In some embodiments, the planarization process is a chemical mechanical grinding process.

In some embodiments, the material of the cladding layer includes resin.

In some embodiments, a side surface of the chip stacked structure is mounted on the upper surface of the carrier board through a temporary bonding layer.

In some embodiments, mounting a side surface of the chip stacked structure on the upper surface of the carrier board includes: mounting a side surface of a chip stacked structure on the upper surface of the carrier board.

In some embodiments, mounting a side surface of the chip stacked structure on the upper surface of the carrier board includes: mounting a side surface of a plurality of chip stacked structures on the upper surface of the carrier board.

In some embodiments, a side surface of a plurality of chip stacked structures is mounted on the upper surface of the carrier board, and the plurality of chip stacked structures are arranged in an array.

In some embodiments, after forming solder bumps electrically connected with the side solder pads, the method further includes: dicing the cladding layer to form a plurality of discrete chip stacked structures with a cladding layer.

In some embodiments, forming solder bumps electrically connected with the side solder pads includes: forming solder bumps directly electrically connected with the side solder pads.

In some embodiments, forming solder bumps electrically connected with the side solder pads includes: after the planarization process, forming a redistribution layer on the surface of the planarized cladding layer, the redistribution layer is electrically connected with the side solder pads; and forming solder bumps on the surface of the redistribution layer, the solder bumps are electrically connected with the redistribution layer.

In some embodiments, the redistribution layer includes a passivation layer and a plurality of discrete redistribution metal layers located in the passivation layer, and the redistribution metal layers are electrically connected with corresponding side solder pads and solder bumps.

In some embodiments, the side solder pads having non-coplanar defects include: a part of side solder pads on the side surfaces of different first semiconductor chips in the chip stacked structure are non-coplanar, and side solder pads on the side surfaces of the same first semiconductor chip are coplanar.

In some embodiments, the side solder pads having non-coplanar defects include: a part of side solder pads on the side surfaces of different first semiconductor chips in the chip stacked structure are non-coplanar, and a part of side solder pads on the side surfaces of the same first semiconductor chip are non-coplanar.

In another aspect, the present disclosure further provides a package structure, which includes: a substrate, the upper surface of the substrate has a plurality of discrete first solder pads; a chip stacked structure located on the upper surface of the substrate, the chip stacked structure includes a plurality of first semiconductor chips stacked in sequence along a direction parallel to the upper surface of the substrate, and a surface of the chip stacked structure close to and parallel to the upper surface of the substrate exposes side solder pads on the corresponding side surfaces of the plurality of first semiconductor chips; a cladding layer covering the chip stacked structure, and the cladding layer exposes the side solder pads; a redistribution layer located at a surface of the cladding layer and the chip stacked structure close to and parallel to the upper surface of the substrate, the redistribution layer is electrically connected with the side solder pads; and solder bumps located between the redistribution layer and the upper surface of the substrate, the solder bumps solder the redistribution layer together with the corresponding first solder pads.

In some embodiments, each of the first semiconductor chips in the chip stacked structure includes opposed active surface and back surface that are perpendicular to the upper surface of the substrate, as well as four side surfaces located between the active surface and the back surface, and one of the side surfaces of the first semiconductor chips close to and parallel to the upper surface of the substrate has in it the side solder pads and exposes the surfaces of the side solder pads, the active surfaces and back surfaces of the first semiconductor chips of the upper and lower layers in the chip stacked structure are arranged opposed to each other.

In some embodiments, there are no electrical connections between the first semiconductor chips of the upper layer and the semiconductor chips of the adjacent lower layer, and an adhesive layer or a bonding layer is provided between the active surfaces or back surfaces of the first semiconductor chips of the upper layer and the corresponding back surfaces or active surfaces of the semiconductor chips of the adjacent lower layer.

In some embodiments, there are electrical connections between the first semiconductor chips of the upper layer and the semiconductor chips of the adjacent lower layer; the active surfaces of the first semiconductor chips have external solder pads, the first semiconductor chips have in them through-hole connection structures electrically connected with the external solder pads, and the back surfaces of the first semiconductor chips expose an end surface of the through-hole connection structures, and the external solder pads on the active surfaces or the through-hole connection structures on the back surfaces of the first semiconductor chips in the upper layer are soldered together with the through-hole connection structures on the corresponding back surfaces or the external solder pads on the active surfaces of the semiconductor chips of the adjacent lower layer.

In some embodiments, the side solder pads and the wiring layers of the first semiconductor chips are one-piece structures.

In some embodiments, the redistribution layer includes a passivation layer and a plurality of discrete redistribution metal layers located in the passivation layer, and the redistribution metal layers are electrically connected with corresponding side solder pads and solder bumps.

In some embodiments, it further includes: a second semiconductor chip mounted on the upper surface of the substrate on a side of the chip stacked structure, the second semiconductor chip is soldered together with corresponding first solder pads.

### BRIEF DESCRIPTION OF THE DRAWINGS

In order to more clearly explain the technical solutions in the embodiments of the present disclosure, the accompanying drawings required for the embodiments will be briefly introduced below, and it is obvious that the accompanying drawings described below are only some embodiments of the present disclosure, and for those ordinary skilled in the art, other accompanying drawings can be obtained according to these accompanying drawings without inventive effort.

FIG. 1 is a structural schematic diagram after providing a chip stacked structure in the method for forming a package structure provided in some embodiments of the present disclosure;

FIG. 2 is a structural schematic diagram after mounting a side surface of the chip stacked structure on the upper surface of the carrier board in the method for forming a package structure provided in some embodiments of the present disclosure;

FIG. 3 is a structural schematic diagram of forming a cladding layer covering the chip stacked structure in the method for forming a package structure provided in some embodiments of the present disclosure;

FIG. 4 is a structural schematic diagram after using a planarization process to remove a part of the cladding layer, a part of the side surface of the chip stacked structure far away from the upper surface of the carrier board, and a part of the side solder pads, in the method for forming a package structure provided in some embodiments of the present disclosure;

FIG. 5 is a structural schematic diagram after forming solder bumps electrically connected with the side solder pads in the method for forming a package structure provided in some embodiments of the present disclosure;

FIG. 6 is a structural schematic diagram after removing the carrier board in the method for forming a package structure provided in some embodiments of the present disclosure;

FIG. 7 is a structural schematic diagram after mounting the side surface of the chip stacked structure exposing side solder pads on the upper surface of the substrate, such that the solder bumps are soldered together with the corresponding first solder pads, in the method for forming a package structure provided in some embodiments of the present disclosure;

FIG. 8 is a structural schematic diagram after forming the redistribution layer in the method of forming the package structure provided in other embodiments of the present disclosure;

FIG. 9 is a structural schematic diagram after forming solder bumps connected with the redistribution layer in the method of forming the package structure provided in other embodiments of the present disclosure;

FIG. 10 is a structural schematic diagram after removing the carrier board in the method of forming the package structure provided in other embodiments of the present disclosure; and

FIG. 11 is a structural schematic diagram after mounting the side surface of the chip stacked structure exposing side solder pads on the upper surface of the substrate, such that the solder bumps on the redistribution layer are soldered together with the corresponding first solder pads, in the method for forming a package structure provided in other embodiments of the present disclosure.

### DETAILED DESCRIPTION

In order to facilitate understanding of the present disclosure, a more comprehensive description of the present disclosure will be provided below with reference to the relevant accompanying drawings. The embodiments of the present disclosure are shown in the accompanying drawings. However, the present disclosure may be implemented in many different forms and is not limited to the embodiments described in the present article. On the contrary, the object of providing these embodiments is to make the disclosure of the present disclosure more thorough and comprehensive.

Unless otherwise defined, all technical and scientific terms used in the present article have the same meanings as those commonly understood by those skilled in the art belonging to the present disclosure. The terms used in the description of the present disclosure are only intended to describe the object of the specific embodiments and are not intended to limit the scope of the present disclosure.

It should be understood that when an element or layer is referred to as “on...,” “close to...,” “connected to,” or “coupled to” other elements or layers, it may be directly on, close to, connected to, or coupled to other elements or layers, or there may be intervening elements or layers. On the contrary, when an element is referred to as “directly on...,” “directly close to...,” “directly connected to,” or “directly coupled to” other elements or layers, there are no intervening elements or layers. It should be understood that although terms such as first, second, third, etc. may be used to describe various elements, components, areas, layers, doping types, and/or portions, these elements, components, areas, layers, doping types, and/or portions should not be limited by these terms. These terms are only used to distinguish one element, component, area, layer, doping type or portion from another element, component, area, layer, doping type or portion. Therefore, without departing from the teachings of the present disclosure, the first element, component, area, layer, doping type, or portion discussed below may be represented as a second element, component, area, layer, or portion.

Spatial relationship terms such as “below,” “under,” “subsequent to,” “beneath,” “above,” “upon,” etc. may be used herein to describe the relationship of an element or feature shown in the figure to other elements or features. It should be understood that in addition to the orientation shown in the figure, spatial relationship terms also include different orientations of devices during use and operation. For example, if the device in the figure is flipped, an element or feature described as “below another element” or “underneath it” or “below it” will be oriented “above” other elements or features. Therefore, the exemplary terms “under” and “below” may include both upper and lower orientations. Furthermore, the device may also include alternative orientations (e.g., rotation 90 degrees or other orientations), and the spatial descriptors used herein are explained accordingly.

When used herein, singular forms of “one,” “a,” and “the/this” may also include plural forms, unless otherwise indicated clearly in the context. It should also be understood that terms such as “includes/contains” or “have,” etc., indicate the presence of the stated features, entities, steps, operations, components, portions, or combinations thereof, but do not preclude the possibility of the presence or addition of one or more other features, entities, steps, operations, components, portions, or combinations thereof. Meanwhile, in the present description, the term “and/or” includes any and all combinations of the items listed in relation thereto.

The structures of the embodiments of the present disclosure should not be limited to the specific shapes shown in the accompanying drawings of the description, but include shape deviations caused by, for example, manufacturing technologies.

It can be understood that in the accompanying drawings of the present disclosure, some adjacent film layers with the same processed film layer material in some figures are drawn as connected to make them similar to the actual structure.

3D package technology is the process of stacking different chips, such as CPUs, accelerators, memory, I/O, and power management, etc., to form a three-dimensional structure. The main advantages of 3D package technology include: 3D package technology makes a plurality of chips to be stacked together in sequence along a direction perpendicular to the substrate, so that the integration level and performance of the chips are improved; and compared to traditional planar connection methods, the total wiring length between chips is reduced to increase bandwidth and improve signal latency, so that the reliability and stability of the package structure are improved.

In existing 3D package technologies, a plurality of semiconductor chips are typically stacked in sequence along a direction perpendicular to the upper surface of the substrate, and this stacked method occupies a large substrate area and is not conducive to heat dissipation, consequently, a 3D package technology has emerged that makes a plurality of semiconductor chips to be stacked in sequence along a direction parallel to the upper surface of the substrate, which improves integration level, meanwhile facilitates heat dissipation for the stacked chips, and in this 3D package technology, when the semiconductor chips are electrically connected with the substrate, the side solder pads on the side surfaces of the semiconductor chips are soldered together with the corresponding side solder pads on the substrate, and this method may cause soldering defects such as cold solder joints, solder joint detachment, or solder bridging, etc.

Through research, it has been found that when a plurality of semiconductor chips are stacked in sequence along a direction parallel to the upper surface of the substrate, a problem exists that the side solder pads exposed on the side surfaces of the semiconductor chips may be non-coplanar or uneven, which causes the solder balls connected with the corresponding side solder pads, formed on the side surfaces of the stacked chip structure to be uneven in height, consequently, when solder balls on the side surfaces of the stacked chip structure are soldered together with the corresponding solder pads on the substrate, soldering defects such as cold solder joints, solder joint detachment, or solder bridging, etc. may occur.

For this purpose, the embodiments of the present disclosure provide a package structure and a method for forming the same, a chip stacked structure, in which side solder pads have non-coplanar defects, is mounted on the upper surface of a carrier board such that the side surface of the chip stacked structure exposing the side solder pads is far away from the upper surface of the carrier board; subsequently, a cladding layer is formed to cover the chip stacked structure; next, a planarization process is used to remove a part of the cladding layer, a part of the side surface of the chip stacked structure far away from the upper surface of the carrier board, and a part of the side solder pads, such that the side solder pads of the different first semiconductor chips exposed on the side surface of the chip stacked structure far away from the upper surface of the carrier board are coplanar, after the planarization process, when solder bumps electrically connected with the side solder pads are formed, since the side solder pads are all coplanar, the formed solder bumps are prevented from being uneven in height, subsequently, when the side surface of the chip stacked structure exposing side solder pads is mounted on the upper surface of the substrate, such that the solder bumps are soldered together with the corresponding first solder pads on the upper surface of the substrate, so that the occurrence of soldering defects such as cold solder joints, solder joint detachment, or solder bridging, etc. can be prevented.

The beneficial effects of the present disclosure include the following.

In the package structure and method for forming the same of the present disclosure, at first a chip stacked structure is provided, the chip stacked structure includes a plurality of first semiconductor chips stacked in sequence, and the chip stacked structure includes four side surfaces, and a side surface of the chip stacked structure exposes side solder pads of the corresponding side surfaces of the plurality of first semiconductor chips, and the side solder pads have non-coplanar defects; subsequently, the chip stacked structure is mounted on the upper surface of the carrier board, such that after the side surface of the chip stacked structure exposing the side solder pads is far away from the upper surface of the carrier board, a cladding layer is formed to cover the chip stacked structure; a planarization process is used to remove a part of the cladding layer, a part of the side surface of the chip stacked structure far away from the upper surface of the carrier board, and a part of the side solder pads, such that the side solder pads of the different first semiconductor chips exposed on the side surface of the chip stacked structure far away from the upper surface of the carrier board are coplanar; after the planarization process, solder bumps electrically connected with the side solder pads are formed; the carrier board is removed; a substrate is provided, the upper surface of the substrate has a plurality of discrete first solder pads; and the side surface of the chip stacked structure exposing the side solder pads is mounted on the upper surface of the substrate, such that the solder bumps are soldered together with the corresponding first solder pads. In the present disclosure, by means of the aforementioned steps, the side solder pads with non-coplanar defects in the chip stacked structure can be easily made to be coplanar through the planarization process, and after the planarization process, solder bumps electrically connected with the side solder pads are formed; since the side solder pads on the side surface of the chip stacked structure are coplanar after the planarization process, the formed solder bumps will not have unevenness problems, therefore, the side surface of the chip stacked structure exposing side solder pads is mounted on the upper surface of the substrate, such that when the solder bumps are soldered together with the corresponding first solder pads on the upper surface of the substrate, no soldering defects such as cold solder joints, solder joint detachment, or solder bridging, etc., will occur between the solder bumps on the side solder pads and the first solder pads on the upper surface of the substrate.

The package structure and the method for forming the same provided by the embodiments of the present disclosure will be described below in conjunction with the accompanying drawings.

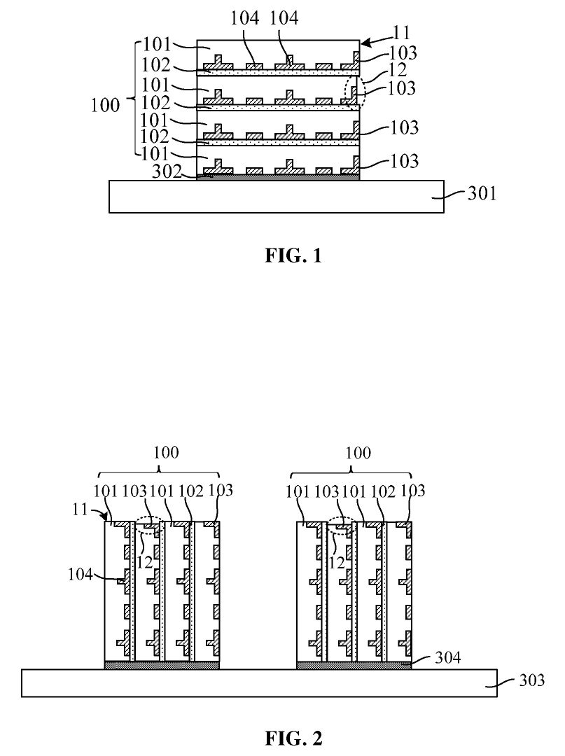

The embodiments of the present disclosure first provide a method for forming a package structure. FIGS. 1-7 are structural schematic diagrams of the formation process of the package structure provided in some embodiments of the present disclosure. The formation process of the package structure is described in detail below in conjunction with the accompanying drawings in some embodiments.

Referring to FIG. 1, a chip stacked structure 100 is provided, the chip stacked structure 100 includes a plurality of first semiconductor chips 101 stacked in sequence, and the chip stacked structure 100 includes four side surfaces, and a side surface 11 of the chip stacked structure 100 exposes side solder pads 103 on the corresponding sides of the plurality of first semiconductor chips 101, and the side solder pads 103 have non-coplanar defects.

The plurality of first semiconductor chips 101 are stacked in sequence in the chip stacked structure 100, and the specific number of first semiconductor chips 101 may be two, three, four, or more. In FIG. 1, the chip stacked structure 100 with four first semiconductor chips 101 is taken as an example for illustration.

In some embodiments, the process of providing the chip stacked structure 100 includes: providing a temporary carrier board 301 and a plurality of first semiconductor chips 101, each of the first semiconductor chips 101 includes opposed active surface and back surface, as well as four side surfaces located between the active surface and the back surface, and one of the side surfaces of the first semiconductor chips 101 has side solder pads 103, and exposes the surfaces of the side solder pads 103; mounting the plurality of first semiconductor chips 101 in sequence on the upper surface of the temporary carrier board 301 in a direction perpendicular to the upper surface of the temporary carrier board 301, and the active surface and the back surface of each first semiconductor chip 101 are parallel to the upper surface of the temporary carrier board 301, the four side surfaces of the first semiconductor chip 101 are perpendicular to the upper surface of the temporary carrier board 301; forming the chip stacked structure 100, and a first semiconductor chip 101 on the bottommost layer is mounted on the upper surface of the temporary carrier board 301 through an adhesive layer 302; after forming the chip stacked structure 100, removing the temporary carrier board 301 to facilitate subsequent processes.

The active surfaces of the first semiconductor chips 101 are a surface on which semiconductor devices (not shown in the figure) and a wiring layer 104 electrically connected with the semiconductor devices are formed, and the back surface is the surface opposed to the active surface, and the four side surfaces are located between the back surface and the active surface; a side surface of the first semiconductor chips 101 exposes side solder pads 103, and the side solder pads 103 are electrically connected with the corresponding wiring layer 104, and the side solder pads 103 serve as connection ports of the first semiconductor chips 101 in the chip stacked structure 100 and other structures (such as a substrate provided later in the present disclosure), and the number of side solder pads 103 exposed on a side surface of the first semiconductor chips 101 is at least one, specifically, it may be one or a plurality of separate ones.

In the chip stacked structure 100, the side surface of the plurality of first semiconductor chips 101 exposing side solder pads 103 is located on the same side surface of the chip stacked structure 100, such as the side surface 11 of the chip stacked structure 100.

Due to manufacturing reasons of the first semiconductor chips 101 (such as process error reasons during the formation of the side solder pads, or dicing accuracy reasons when dicing a wafer to form a plurality of discrete first semiconductor chips 101) and/or stacking process reasons when stacking a plurality of first semiconductor chips 101 at once (such as alignment error reasons during stacking), the side solder pads 103 in the formed chip stacked structure 100 may have non-coplanar defects, and the non-coplanar defects refer to a situation where, in a plurality of side solder pads 103 exposed on the side surface 11 of the chip stacked structure 100, the exposed surfaces of one or more side solder pads 103 are not in the same plane as the exposed surfaces of other side solder pads 103, for example, the exposed surfaces of the side solder pads 103 in the dashed box 12 in FIG. 1 are not in the same plane as the exposed surfaces of other side solder pads 103, and if the side solder pads 103 on the side surface 11 of the chip stacked structure 100 which has non-coplanar defects, are soldered with other structures (such as substrates), then due to the non-coplanar defects of the side solder pads 103, the solder bumps formed on the side solder pads will be uneven, which will easily lead to problems of cold solder joints, solder joint detachment, or solder bridging between a part of the side solder pads 103 in the chip stacked structure 100 and other structures (such as substrates), thus affecting the quality of the soldering.

In an embodiment, the presence of non-coplanar defects on the side solder pads 103 includes: a part of side solder pads 103 on the side surfaces of different first semiconductor chips 101 in the chip stacked structure 100 are non-coplanar, and the side solder pads 103 on the side surface of the same first semiconductor chip 101 are coplanar.

In another embodiment, the presence of non-coplanar defects on the side solder pads 103 includes: a part of side solder pads 103 on the side surfaces of different first semiconductor chips 101 in the chip stacked structure 100 are non-coplanar, and a part of side solder pads 103 on the side surface of the same first semiconductor chip 101 are non-coplanar.

In an embodiment, the side solder pads are manufactured and formed synchronously with wiring layers of the first semiconductor chips, which specifically includes: forming lines on the side surfaces of the corresponding dicing lanes of the chips synchronously with manufacturing the wiring layer 104 on the active surfaces of the first semiconductor chips, and after the chips are diced, the corresponding side surfaces of the first semiconductor chips 101 expose the lines to form side solder pads 103. Therefore, the side solder pads and the wiring layers 104 of the first semiconductor chips are one-piece structure.

In some embodiments, referring again to FIG. 1, when a plurality of first semiconductor chips 101 are stacked in sequence to form the chip stacked structure 100, the active surfaces of the first semiconductor chips 101 of the upper layer and the back surfaces of the first semiconductor chips 101 of the adjacent lower layer are arranged opposed to each other. In other embodiments, when a plurality of first semiconductor chips 101 are stacked in sequence to form the chip stacked structure 100, the back surfaces of the first semiconductor chips 101 of the upper layer and the active surfaces of the first semiconductor chips 101 of the adjacent lower layer are arranged opposed to each other.

In some embodiments, referring again to FIG. 1, there are no electrical connections between the first semiconductor chips 101 of the upper layer and the semiconductor chips of the adjacent lower layer; and an adhesive layer or a bonding layer 102 is provided between the active surfaces or back surfaces of the first semiconductor chips 101 of the upper layer and the corresponding back surfaces or active surfaces of the semiconductor chips of the adjacent lower layer, in one specific example, a bonding layer 102 is provided between the active surfaces of the first semiconductor chips 101 of the upper layer and the corresponding back surfaces of the semiconductor chips of the adjacent lower layer, or an adhesive layer or bonding layer 102 is provided between the back surfaces of the first semiconductor chips 101 of the upper layer and the corresponding active surfaces of the semiconductor chips of the adjacent lower layer. When there are no electrical connections between the first semiconductor chips 101 of the upper layer and the semiconductor chips of the adjacent lower layer, the first semiconductor chips 101 in the chip stacked structure 100 communicate and/or transmit data with other structures (such as substrates) through side solder pads 103, and communication and/or data transmission between adjacent first semiconductor chips 101 can be performed through the substrate.

In other embodiments, there are electrical connections between the first semiconductor chips 101 of the upper layer and the semiconductor chips of the adjacent lower layer, such that for the first semiconductor chips 101 in the chip stacked structure 100 in addition to communicating and/or transmitting data with other structures (such as the substrate) through the side solder pads 103, communication and/or data transmission can also be directly performed between adjacent first semiconductor chips (without through the substrate), and the length of the signal or data transmission path between adjacent first semiconductor chips 101 is shortened, and consequently the performance of the chip stacked structure 100 is improved; in an example, the active surfaces of the first semiconductor chips 101 have external solder pads (not shown in the figure), and the first semiconductor chips 101 have in them through-hole connection structures (not shown in the figure) electrically connected with the external solder pads, and the back surfaces of the first semiconductor chips 101 expose an end surface of the through-hole connection structures, and the external solder pads on the active surfaces or the through-hole connection structures on the back surfaces of the first semiconductor chips 101 in the upper layer are soldered together with the through-hole connection structures on the corresponding back surfaces or the external solder pads on the active surfaces of the semiconductor chips of the adjacent lower layer; in an example, the external solder pads on the active surfaces of the first semiconductor chips 101 of the upper layer are soldered together with the through-hole connection structures on the corresponding back surfaces of the semiconductor chips of the adjacent lower layer, or the through-hole connection structures on the back surfaces of the first semiconductor chips 101 of the upper layer are soldered together with the external solder pads on the corresponding active surfaces of the semiconductor chip of the adjacent lower layer. The soldering includes a solder soldering process or a hybrid bonding soldering process; the solder soldering process may use a Thermal Compression (TC) bonding of Non-Conductive Film (NCF) (TC-NCF) process or a Mass Reflow bonding with Molded UnderFill (MR-MUF) process; the external solder pads of the first semiconductor chips 101 in the upper and lower layers and the corresponding through-hole connection structures are soldered together by means of the respective solder, and an isolation layer is also fully filled between the first semiconductor chips 101 in the upper and lower layers. The hybrid bonding soldering process is to bond the bonding layer on the active surfaces of the first semiconductor chips 101 of the upper layer together with the bonding layer on the back surfaces of the first semiconductor chips 101 of the lower layer, and the bonding layer includes a silicon oxide layer and metal solder pads located in the silicon oxide layer, and the surfaces of the metal solder pads are exposed by the silicon oxide layer.

In the chip stacked structure 100, the functions of the plurality of first semiconductor chips 101 are the same or different. In some embodiments, when the functions of the plurality of first semiconductor chips 101 are the same, the internal structures of the plurality of first semiconductor chips 101 are the same. In another embodiment, when the functions of the plurality of first semiconductor chips 101 are the same, the internal structures of the plurality of first semiconductor chips 101 are different.

According to the different functions, the first semiconductor chips 101 may include logic chips and/or memory chips. In some embodiments, the logic chips may include, but are not limited to, gate arrays, unit base arrays, embedded arrays, structured Application-Specific Integrated Circuits (ASICs), Field-Programmable Gate Arrays (FPGAs), Complex Programmable Logic Devices (CPLDs), Graphics Processing Units (GPUs), Central Processing Units (CPUs), MicroProcessor Units (MPUs), MicroController Units (MCUs), logic Integrated Circuits (ICs), Application Processors (APs), Display Driver ICs (DDIs), Radio Frequency (RF) chips, power supply chips, or Complementary Metal-Oxide-Semiconductor (CMOS) image sensors. In some embodiments, the memory chips may include, but are not limited to, Dynamic Random-Access Memories (DRAMs), Static Random-Access Memories (SRAMs), Magnetoresistive Random-Access Memories (MRAMs), Phase-Change Memories (PRAMs), Resistive Random-Access Memories (RRAMs), or non-volatile memory chips (such as flash memories).

In some embodiments, the functions of all first semiconductor chips 101 in the chip stacked structure 100 are the same. In one specific example, all first semiconductor chips 101 in the chip stacked structure 100 are memory chips. In another specific example, all first semiconductor chips 101 in the chip stacked structure 100 may also be logic chips.

In other embodiments, the functions of a part of the first semiconductor chips 101 in the chip stacked structure 100 are different from the functions of other parts of the first semiconductor chips 101. In one example, a part of the first semiconductor chips 101 in the chip stacked structure 100 are logic chips, and a part of the first semiconductor chips 101 are all memory chips.

Referring to FIG. 2, a carrier board 303 is provided, and a side surface of the chip stacked structure 100 is mounted on the upper surface of the carrier board 303, such that the side surface 11 of the chip stacked structure 100 exposing the side solder pads 103 is far away from the upper surface of the carrier board 303.

In some embodiments, a side surface of the chip stacked structure 100 is mounted on the upper surface of the carrier board 303 through a temporary bonding layer 304. The temporary bonding layer 304 may be an adhesive layer.

In some embodiments, mounting a side surface of the chip stacked structure 100 on the upper surface of the carrier board 303 includes: mounting a side surface of one chip stacked structure 100 on the upper surface of the carrier board 303.

In some embodiments, mounting a side surface of the chip stacked structure 100 on the upper surface of the carrier board 303 includes: mounting a side surface of a plurality of chip stacked structures 100 on the upper surface of the carrier board 303, through subsequent processes, the side surfaces of the plurality of chip stacked structures 100 with side solder pads can be planarized simultaneously, so that the side solder pads on the corresponding side surfaces of the plurality of chip stacked structures 100 are coplanar to improve processing efficiency. In some embodiments, a side surface of the plurality of chip stacked structures 100 are mounted on the upper surface of the carrier board 303, and the plurality of chip stacked structures 100 are arranged in an array to facilitate subsequent processes.

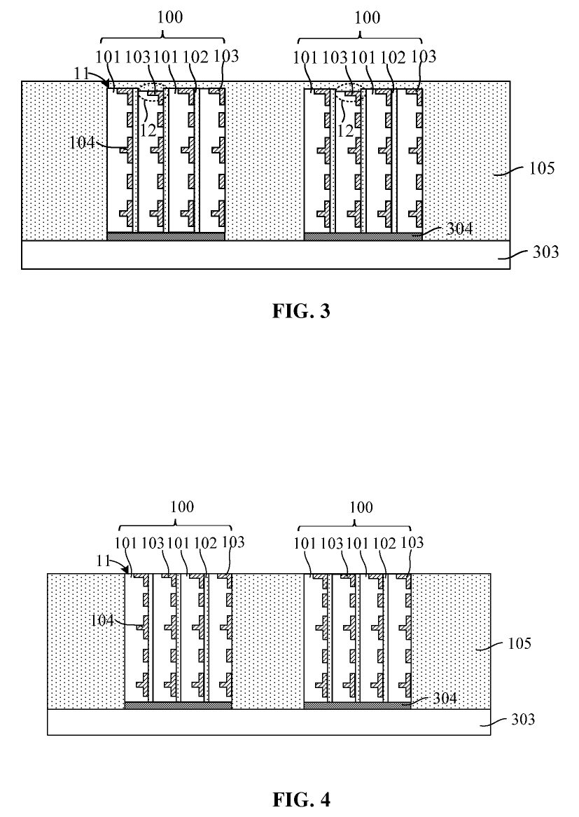

Referring to FIG. 3, a cladding layer 105 is formed to cover the chip stacked structures 100.

In some embodiments, the material of the cladding layer 105 includes a resin, specifically, the material of the cladding layer 105 may be epoxy resin, polyimide resin, benzocyclobutene resin, or polybenzoxazole resin with or without fillers; or it may also be polybutylene terephthalate, polycarbonate, polyethylene terephthalate, polyethylene, polypropylene, polyolefin, polyurethane, polyethersulfone, polyamide, polyurethane, ethylene-vinyl acetate copolymer or polyvinyl alcohol with fillers. The fillers may be inorganic fillers or organic fillers. The process for forming the cladding layer 105 includes compression molding or transfer molding.

Referring to FIG. 4, a planarization process is used to remove a part of the cladding layer 105, a part of the side surfaces of the chip stacked structures 100 far away from the upper surface of the carrier board 303 and a part of the side solder pads 103, such that the side solder pads 103 of the different first semiconductor chips 101 exposed on the side surfaces 11 of the chip stacked structures 100 far away from the upper surface of the carrier board are coplanar.

That the side solder pads 103 are coplanar means that the exposed surfaces of a plurality of side solder pads 103 in the chip stacked structure 100 are in the same plane, consequently, when solder bumps are formed on the side solder pads 103 in subsequent steps, the solder bumps will not have problems of unevenness, and when connecting the chip stacked structure 100 after the planarization process with other structures (such as substrates), the occurrence of soldering defects (such as cold solder joints, solder detachment, or solder bridging) can be prevented when the solder bumps on the side solder pads of the side surface 11 of the chip stacked structure 100 are soldered to other structures (such as the first solder pads of the substrates), so that the performance of the package structure is improved.

In some embodiments, the planarization process is a chemical mechanical grinding process.

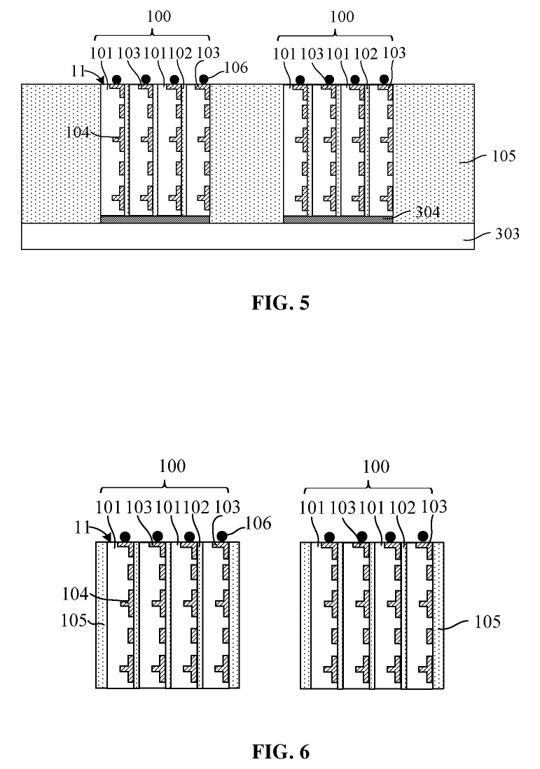

Referring to FIG. 5, after the planarization process, solder bumps 106 electrically connected with the side solder pads 103 are formed.

The solder bumps 106 are formed directly on the surfaces of the side solder pads 103.

In some embodiments, the solder bumps 106 are solder balls. In other embodiments, the solder bumps 106 may include metal pillars (or metal bumps) and solder caps located at the tops of the metal pillars. The material of the solder bumps 106 is one or more of aluminum, copper, titanium, nickel, tin, tungsten, platinum, chromium, tantalum, gold, and silver, and the material of the solder balls or solder caps is one or more of tin, tin-silver, tin-indium, tin-gold, tin-copper, tin-lead, tin-silver-copper, tin-silver-zinc, tin-zinc, tin-bismuth-indium, tin-zinc-indium, or tin-silver-antimony.

Referring to FIG. 6, the carrier board 303 (referring to FIG. 5) is removed.

In some embodiments, when there is only one chip stacked structure 100 on the carrier board 303, the carrier board 303 is removed directly.

In other embodiments, referring again to FIGS. 5 and 6, when there are a plurality of chip stacked structures 100 on the carrier board 303, after forming solder bumps 106 electrically connected with the side solder pads 103, the process further includes: dicing the cladding layer 105 to form a plurality of discrete chip stacked structures 100 with a cladding layer 105; after dicing, removing the carrier board 303.

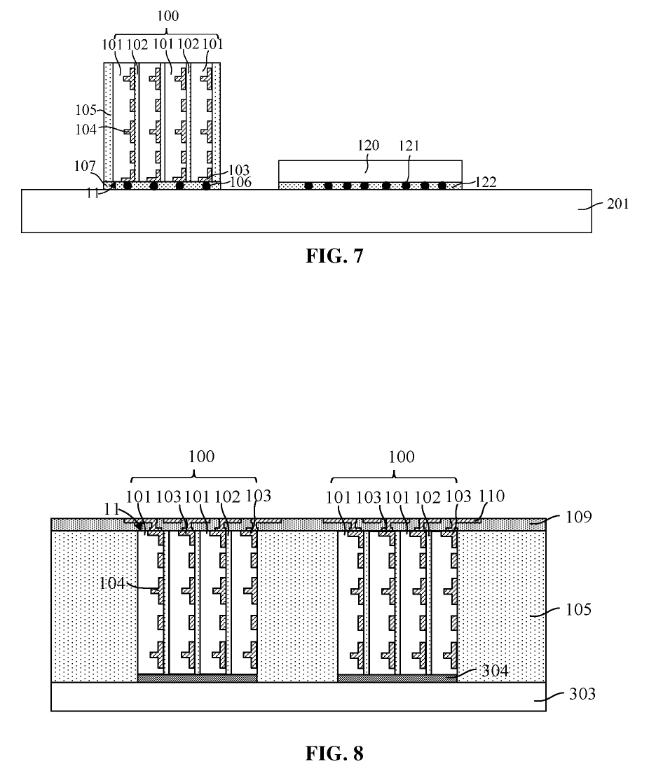

Referring to FIG. 7, a substrate 201 is provided, the upper surface of the substrate 201 has a plurality of discrete first solder pads (not shown in the figure); the side surface of the chip stacked structure 100 exposing the side solder pads 103 is mounted on the upper surface of the substrate 201, such that the solder bumps 106 are soldered together with the corresponding first solder pads.

In some embodiments, the substrate 201 may include opposed upper surface and lower surface; the upper surface of the substrate 201 has a plurality of discrete first solder pads (not shown in the figure), the lower surface of the substrate 201 has a plurality of discrete second solder pads (not shown in the figure), and the substrate 201 has in it a first line (not shown in the figure), and a part of the first line may be used for electrical connection between the first solder pads on the upper surface of the substrate 201 and the corresponding second solder pads on the lower surface of the substrate 201, and a part of the first line may also be used for electrical connection between a part of the first solder pads on the upper surface of the substrate 201, and a part of the first line may also be used for electrical connection between a part of the second solder pads on the lower surface of the substrate 201. A part of the first solder pads on the upper surface of the substrate 201 are soldered together with corresponding side solder pads of the chip stacked structure 100, and external solder bumps (not shown in the figure) may be formed on the second solder pads on the lower surface of the substrate 201; and the external solder bumps are used to connect with other devices, other substrates, or package structures. The material of the first solder pads, the second solder pads, and the first line is metal, specifically, it may be one or more of aluminum, copper, nickel, tin, titanium, tungsten, platinum, chromium, tantalum, gold, and silver. The material of the external solder bumps is tin or a tin alloy, wherein the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

In some embodiments, the substrate 201 may be one of a resin substrate, a silicon substrate, a Printed Circuit Board (PCB), a ReDistribution Layer (RDL), a ceramic substrate, a glass substrate, or a Flexible Printed Circuit board (FPC). In some embodiments, the substrate 201 may be a single-layer board or a multilayer board. In some embodiments, the substrate 201 may serve as an interposer.

In some embodiments, the method further includes: mounting a second semiconductor chip 120 on the upper surface of the substrate 201 on a side surface of the chip stacked structure 100, the second semiconductor chip 120 is soldered together with the corresponding first solder pads on the upper surface of the substrate 201; In an embodiment, the second semiconductor chip 120 is mounted in a flip-chip manner on the upper surface of the substrate 201, and the solder bumps 121 on the second semiconductor chip 120 are soldered together with the corresponding first solder pads on the upper surface of the substrate 201. In some embodiments, the second semiconductor chip 120 may be electrically connected with the chip stacked structure 100 through the first line in the substrate 201, and communication and/or data transfer may be performed between the second semiconductor chip 120 and the chip stacked structure 100. In some embodiments, the second semiconductor chip 120 includes a CPU chip or a GPU chip.

In some embodiments, a first underfill layer 107 is also filled between the chip stacked structure 100 and the upper surface of the substrate 201. A second bottom fill layer 122 is also filled between the second semiconductor chip 120 and the upper surface of the substrate 201.

Other embodiments of the present disclosure also provide a method for forming a package structure, and the main difference between these embodiments and the aforementioned embodiments lies in: the solder bumps are electrically connected with corresponding side solder pads in the chip stacked structure through a redistribution layer, through the redistribution layer, the external terminals on the side surface of the chip stacked structure can be redistributed, so that the density of external terminals on the side surface of the chip stacked structure is increased. FIGS. 8-11 are structural schematic diagrams of the formation process of the package structure provided in other embodiments of the present disclosure.

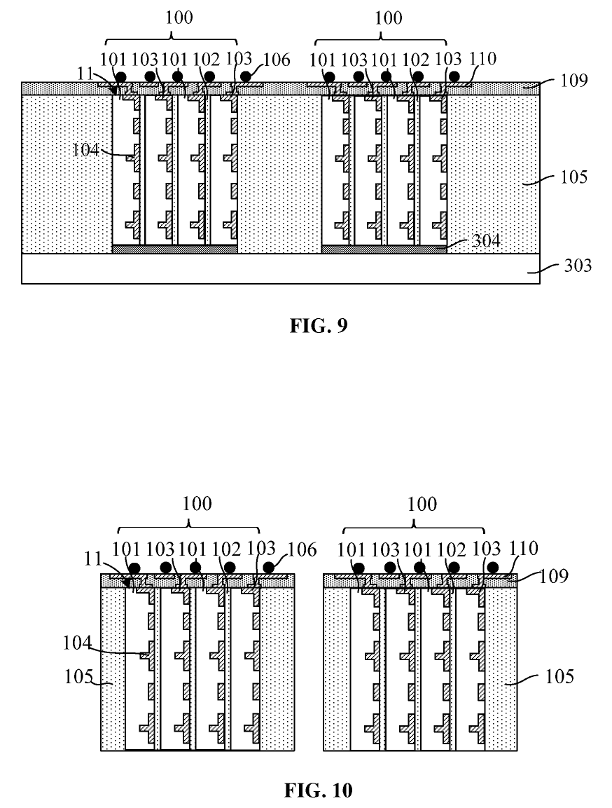

Referring to FIG. 8, a planarization process is used to remove a part of the cladding layer 105, a part of the side surface of the chip stacked structure 100 far away from the upper surface of the carrier board 303, and a part of the side solder pads 103, such that the side solder pads 103 of different first semiconductor chips 101 exposed on the side surface of the chip stacked structure 100 far away from the upper surface of the carrier board 303 are coplanar, then a redistribution layer is formed on the surface of the planarized cladding layer 105, and the redistribution layer is electrically connected with the side solder pads 103; in a specific example, the redistribution layer includes a passivation layer 109 and a plurality of discrete redistribution metal layers 110 located in the passivation layer 109, and the redistribution metal layers 110 are electrically connected with the corresponding side solder pads 103; referring to FIG. 9, solder bumps 106 are formed on the surface of the redistribution layer, and the solder bumps 106 are electrically connected with the redistribution layer, in a specific example, the solder bumps 106 are electrically connected with the corresponding redistribution metal layer 110.

The passivation layer 109 includes organic materials or inorganic materials. The organic materials include resin materials or polymers, such as epoxy resin, polyimide resin, benzocyclobutene resin, or polybenzoxazole resin, and the inorganic materials include one or more of silicon oxide, silicon nitride, and silicon oxynitride. The material of the redistribution metal layer 110 is one or more of Al, Cu, Ag, Au, Pt, Ni, Ti, TiN, TaN, Ta, TaC, TaSiN, W, WN, or WSi.

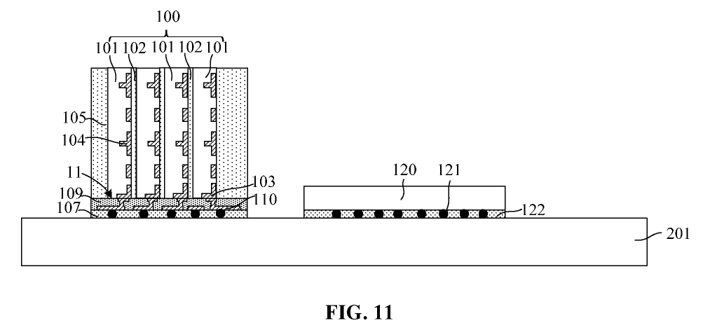

Referring to FIG. 10, the wiring layer and the cladding layer 105 are diced to form a plurality of discrete chip stacked structures 100 with wiring layer and cladding layer 105; the carrier board 303 is removed; referring to FIG. 11, a substrate 201 is provided, the upper surface of the substrate 201 has a plurality of discrete first solder pads (not shown in the figure); a surface of the wiring layer of the chip stack structure 100 with the wiring layer and the cladding layer 105 is mounted on the upper surface of the substrate 201, such that the solder bumps 106 are soldered together with the corresponding first solder pads.

It should be noted that in other embodiments, when the chip stacked structure 100 has two or more side surfaces exposed in the side solder pads 103 of the corresponding side surfaces of the corresponding first semiconductor chip 101, the aforementioned steps (mounting a side surface of the chip stacked structure on the upper surface of the carrier board, forming a cladding layer covering the chip stacked structure; using a planarization process to remove a part of the cladding layer, a part of the side surface of the chip stacked structure far away from the upper surface of the carrier board, and a part of the side solder pads, such that the side solder pads of the different first semiconductor chips exposed on the side surface of the chip stacked structure far away from the upper surface of the carrier board are coplanar; after the planarization process, forming solder bumps electrically connected with the side solder pads) can be used in sequence on each side surface of the chip stacked structure 100 with side solder pads to achieve planarization, such that the side solder pads on the corresponding side surfaces are coplanar, and solder bumps are formed which are connected with the side solder pads on the corresponding side surfaces after the planarization process.

Some embodiments of the present disclosure also provide a package structure, referring to FIG. 11, which includes: a substrate 201, the upper surface of the substrate has a plurality of discrete first solder pads (not shown in the figure); a chip stacked structure 100 located on the upper surface of the substrate 201, the chip stacked structure 100 includes a plurality of first semiconductor chips 101 stacked in sequence along a direction parallel to the upper surface of the substrate 201, and a side surface 11 of the chip stacked structure 100 close to and parallel to the upper surface of the substrate 201 exposes side solder pads 103 on the corresponding side surfaces of the plurality of first semiconductor chips 101; a cladding layer 105 covering the chip stacked structure 100, and the cladding layer 105 exposes the side solder pads 103; a passivation layer or redistribution metal layer (109, 110) located at a surface of the cladding layer 105 and the chip stacked structure 100 close to and parallel to the upper surface of the substrate 201, the redistribution layer is electrically connected with the side solder pads 103; and solder bumps 106 located between the redistribution layer and the upper surface of the substrate 201, the solder bumps 106 solder the redistribution layer together with the corresponding first solder pads.

In some embodiments, the side solder pads 103 and the line layers of the first semiconductor chips 101 are one-piece structure.

In some embodiments, each of the first semiconductor chips 101 in the chip stacked structure 100 includes opposed active surface and back surface that are perpendicular to the upper surface of the substrate 201, as well as four side surfaces located between the active surface and the back surface, and one of the side surfaces of the first semiconductor chips 101 close to and parallel to the upper surface of the substrate 201 has in it the side solder pads 103 and exposes the surfaces of the side solder pads 103, the active surfaces and back surfaces of the first semiconductor chips 101 of the upper and lower layers in the chip stacked structure 100 are arranged opposed to each other.

In some embodiments, there are no electrical connections between the active surfaces or back surfaces of the first semiconductor chips 101 of the upper layer and the semiconductor chips of the adjacent lower layer, and an adhesive layer or a bonding layer 102 is provided between the active surfaces or back surfaces of the first semiconductor chips 101 of the upper layer and the corresponding back surfaces or active surfaces of the semiconductor chips of the adjacent lower layer. The plurality of first semiconductor chips 101 may be electrically connected through the passivation layer or redistribution metal layers (109, 110) on side solder pads 103.

In some embodiments, there are electrical connections between the first semiconductor chips 101 of the upper layer and the semiconductor chips of the adjacent lower layer; the active surfaces of the first semiconductor chips 101 have external solder pads, the first semiconductor chips 101 have in them through-hole connection structures electrically connected with the external solder pads, and the back surfaces of the first semiconductor chips 101 expose an end surface of the through-hole connection structures, and the external solder pads on the active surfaces or the through-hole connection structures on the back surfaces of the first semiconductor chips 101 in the upper layer are soldered together with the through-hole connection structures on the corresponding back surfaces or the external solder pads on the active surfaces of the semiconductor chips of the adjacent lower layer, and an isolation layer is filled between the active surfaces or back surfaces of the first semiconductor chips 101 of the upper layer and the corresponding back surfaces or active surfaces of the semiconductor chips of the adjacent lower layer.

In some embodiments, the redistribution layer includes a passivation layer 109 and a plurality of discrete redistribution metal layers 110 located in the passivation layer 109, and the redistribution metal layers 110 are electrically connected with corresponding side solder pads 103 and solder bumps 106.

In some embodiments, the structure further includes: a second semiconductor chip 120 mounted on the upper surface of the substrate 201 on a side of the chip stacked structure 100, and the second semiconductor chip 120 is soldered together with corresponding first solder pads.

In the description of the present specification, reference to terms such as “some embodiments,” “other embodiments,” “ideal embodiments,” etc., indicate that specific features, structures, materials, or characteristics described in conjunction with the embodiments or examples are included in at least one embodiment or example of the present disclosure. In the present specification, illustrative descriptions of the aforementioned terms do not necessarily refer to the same embodiments or examples.

The various technical features of the aforementioned embodiments may be combined in any manner, in order to make the description concise, not all possible combinations of the various technical features of the aforementioned embodiments have been described; however, as long as there is no contradiction in the combination of these technical features, they should be considered within the scope of the present specification.

The aforementioned embodiments only express a few embodiments of the present disclosure, and their descriptions are relatively specific and detailed, but they should not be understood as limiting the scope of the application. It should be pointed out that for those skilled in the art may also make several modifications and improvements without departing from the concepts of the present disclosure, all of which are within the scope of protection of the present disclosure. Therefore, the scope of protection of the present disclosure shall be determined by the appended claims.

What is claimed is:

1. A method for forming a package structure, comprising:
providing a chip stacked structure, wherein the chip stacked structure comprises a plurality of first semiconductor chips stacked in sequence, the chip stacked structure comprises four side surfaces, and a first side surface of the chip stacked structure exposes side solder pads of the corresponding side surfaces of the plurality of first semiconductor chips, and the side solder pads have non-coplanar defects;
providing a carrier board, mounting a second side surface of the chip stacked structure on an upper surface of the carrier board, such that the first side surface of the chip stacked structure exposing the side solder pads is opposite to the upper surface of the carrier board;
forming a cladding layer covering the chip stacked structure;
using a planarization process to remove a part of the cladding layer, a part of the first side surface of the chip stacked structure opposing to the upper surface of the carrier board, and a part of the side solder pads, such that the side solder pads of different first semiconductor chips exposed on the first side surface of the chip stacked structure opposing to the upper surface of the carrier board are coplanar;
after the planarization process, forming solder bumps electrically connected to the side solder pads;
removing the carrier board;
providing a substrate, wherein an upper surface of the substrate has a plurality of discrete first solder pads; and
mounting the first side surface of the chip stacked structure, exposing the side solder pads on the upper surface of the substrate, such that the solder bumps are soldered together with the corresponding first solder pads.

2. The method for forming a package structure according to claim 1, wherein each of the first semiconductor chips in the chip stacked structure comprises opposing active surfaces and back surfaces, and four side surfaces located between the active surfaces and the back surfaces, and wherein one of the side surfaces of the first semiconductor chips has the side solder pads and exposes surfaces of the side solder pads, and the active surfaces and the back surfaces of the first semiconductor chips of adjacent layers in the chip stacked structure are arranged opposed to each other.

3. The method for forming a package structure according to claim 2, wherein the active surfaces of the first semiconductor chips of an upper layer and the back surfaces of the first semiconductor chips of an adjacent lower layer are arranged opposed to each other.

4. The method for forming a package structure according to claim 2, wherein the back surfaces of the first semiconductor chips of an upper layer and the active surfaces of the first semiconductor chips of an adjacent lower layer are arranged opposed to each other.

5. The method for forming a package structure according to claim 3, wherein there are no direct electrical connections between the first semiconductor chips of the upper layer and the first semiconductor chips of the adjacent lower layer.

6. The method for forming a package structure according to claim 5, wherein an adhesive layer or a bonding layer is provided between the active surfaces or the back surfaces of the first semiconductor chips of the upper layer and the corresponding back surfaces or active surfaces of the first semiconductor chips of the adjacent lower layer.

7. The method for forming a package structure according to claim 3, wherein there are direct electrical connections between the first semiconductor chips of the upper layer and the first semiconductor chips of the adjacent lower layer.

8. The method for forming a package structure according to claim 7, wherein the active surfaces of the first semiconductor chips have external solder pads, the first semiconductor chips comprise through-hole connection structures electrically connected to the external solder pads, and the back surfaces of the first semiconductor chips expose an end surface of the through-hole connection structures, and the external solder pads on the active surfaces or the through-hole connection structures on the back surfaces of the first semiconductor chips in the upper layer are soldered together with the through-hole connection structures on the corresponding back surfaces or the external solder pads on the active surfaces of the semiconductor chips of the adjacent lower layer.

9. The method for forming a package structure according to claim 1, wherein the planarization process is a chemical mechanical grinding process.

10. The method for forming a package structure according to claim 1, wherein a material of the cladding layer comprises resin.

11. The method for forming a package structure according to claim 1, wherein the second side surface of the chip stacked structure is mounted on the upper surface of the carrier board through a temporary bonding layer.

12. The method for forming a package structure according to claim 11, wherein a plurality of chip stacked structures arranged in an array are mounted on the upper surface of the carrier board.

13. The method for forming a package structure according to claim 12, wherein after forming solder bumps electrically connected to the side solder pads, the method further comprises: dicing the cladding layer to separate the array into a plurality of discrete clad chip stacked structures.

14. The method for forming a package structure according to claim 1, wherein forming the solder bumps further comprises: after the planarization process, forming a redistribution layer on a surface of a planarized cladding layer, wherein the redistribution layer is electrically connected to the side solder pads; and
forming the solder bumps on the redistribution layer, such that the solder bumps are electrically connected to the side solder pads through the redistribution layer.

15. The method for forming a package structure according to claim 14, wherein the redistribution layer comprises a passivation layer and a plurality of discrete redistribution metal layers located in the passivation layer, and the redistribution metal layers provide an electrical connection between the corresponding side solder pads and the solder bumps.

16. The method for forming a package structure according to claim 1, wherein the side solder pads are formed concurrently with wiring layers of the first semiconductor chips.

17. The method for forming a package structure according to claim 16, wherein the side solder pads are formed concurrently with wiring layers of the first semiconductor chips further comprises: forming conductive lines within dicing lanes of a wafer during the formation of the wiring layers on active surfaces of the first semiconductor chips, and
dicing the wafer to expose the conductive lines on the corresponding side surfaces of the first semiconductor chips, thereby forming the side solder pads.

18. The method for forming a package structure according to claim 1, wherein the non-coplanar defects of the side solder pads further comprise: at least a first portion of the side solder pads on different first semiconductor chips being non-coplanar with one another; and
at least a second portion of the side solder pads on the same first semiconductor chip are non-coplanar with one another.

19. A package structure, comprising:
a substrate, comprising a plurality of discrete first solder pads on an upper surface of the substrate;
a chip stacked structure located on the upper surface of the substrate, wherein the chip stacked structure comprises a plurality of first semiconductor chips stacked in sequence along a direction parallel to the upper surface of the substrate, wherein a first side surface of the chip stacked structure close to and parallel to the upper surface of the substrate exposes side solder pads of the plurality of first semiconductor chips;
a cladding layer covering the chip stacked structure, wherein the cladding layer exposes the side solder pads;
a redistribution layer located on a surface of the cladding layer and the chip stacked structure close to and parallel to the upper surface of the substrate, wherein the redistribution layer is electrically connected to the side solder pads; and
solder bumps located between the redistribution layer and the upper surface of the substrate, wherein the solder bumps electrically connect the redistribution layer to the corresponding first solder pads.

20. The package structure according to claim 19, wherein the side solder pads and wiring layers of the first semiconductor chips comprise a one-piece structure.
